(19) United States
(12) Patent Application Publication
(10) Pub. No.: US 2008/0075881 A1
(43) Pub. Date: Mar. 27, 2008

(54) Method of Forming A Metallic Oxide Film Using Atomic Layer Deposition

(76) Inventors: Seok-jun Won, Seoul (KR); Ju-youn Kim, Suwon-si (KR); Jung-min Park, Ansan-si (KR)

Correspondence Address: F. CHAU & ASSOCIATES, LLC, 130 WOODBURY ROAD, WOODBURY, NY, 11797, US

(21) Appl. No.: 11/828,897

(22) Filed: Jul. 26, 2007

(30) Foreign Application Priority Data
Jul. 26, 2006 (KR) 10-2006-0070371

(51) Int. Cl. C23C 16/513; C23C 16/56

(52) U.S. Cl. 427/539

(57) ABSTRACT

A method of forming a metallic oxide film using atomic layer deposition includes loading a substrate into a reactor, supplying a metallic source gas into the reactor and absorbing the metallic source gas onto the substrate, purging the remaining metallic source gas that does not react, with the substrate, and directly producing plasma of an N-group-containing oxide reactant gas in the reactor.

### CROSS REFERENCE TO RELATED FOREIGN APPLICATION

This application claims priority from Korean Patent Application No. 10-2006-0070371 filed on Jul. 26, 2006 in the Korean Intellectual Property Office, the contents of which are herein incorporated by reference in their entirety.

### BACKGROUND OF THE INVENTION

1. Field of the Invention

The present disclosure is directed to a method of forming a metallic oxide film using atomic layer deposition, and more particularly, to a method of forming a metallic oxide film using atomic layer deposition that improves productivity.

2. Description of the Related Art

In general, methods of forming a thin film, such as PVD (Physical vapor deposition), CVD (Chemical Vapor Deposition), and ALD (Atomic Layer Deposition) are used to form a thin film of a semiconductor substrate in the process of manufacturing semiconductor elements.

Among these methods, ALD is a method of forming a thin film by supplying gases in the form of an individual pulse at predetermined intervals to form a thin film, instead of supplying the gases at one time. Specifically, a thin film having an atomic thickness is formed by alternately supplying a source gas and a purge gas, and a reactant gas and a purge gas. The ALD provides excellent step coverage so the thin film can be formed with a uniform thickness on a large substrate. Further, the thickness of the thin film can be adjusted by controlling the amount of repetition.

In addition to common ALD, PEALD (Plasma Enhanced Atomic Layer Deposition) that forms a thin film by changing a reactant gas into a plasma state is used. The PEALD has an excellent deposition rate and electrical properties, and allows deposition for a variety of substances.

However, the ALD has a slow rate of deposition as compared with the CVD, so that the useful range is limited. Accordingly, the use of ALD for more fields by improving the rate of deposition is desired.

### SUMMARY OF THE INVENTION

According to an aspect of the present invention, there is provided a method of forming a metallic oxide film using ALD, the method including loading a substrate into a reactor, supplying a metallic source gas into the reactor and absorbing the metallic source gas onto the substrate, purging the metallic source gas that remains without reacting with the substrate, and directly producing plasma of an N-group-containing oxide reactant gas.

### BRIEF DESCRIPTION OF THE DRAWINGS

The above and other features of embodiments of the present invention will become more apparent by describing in detail exemplary embodiments thereof with reference to the attached drawings.

FIG. 1 is a flowchart illustrating a method of forming a metallic oxide film using ALD according to an embodiment of the invention.

FIG. 2 is a flowchart illustrating a method of forming a metallic oxide film using ALD according to another embodiment of the invention.

FIG. 3 is a flowchart, illustrating a method of forming a metallic oxide film using ALD according to another embodiment of the invention.

FIG. 4 is a graph showing results of analyzing absorption rate and desorption rate of a metallic source gas according to the type of metallic reactant plasma producing gases in a method of forming a metallic oxide film using ALD according to an embodiment of the invention.

FIGS. 5 and 6 are graphs showing deposition thicknesses of a metallic oxide film according to the type of metallic reactant plasma producing gases in a method of forming a metallic oxide film using ALD according to an embodiment of the invention.

FIG. 7 is a graph showing analysis results of deposition rate of a metallic oxide film according to the type of metallic reactant plasma producing gases in a method of forming a metallic oxide film using ALD according to an embodiment of the invention.

### DETAILED DESCRIPTION OF THE EXEMPLARY EMBODIMENTS

Features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Like reference numerals refer to like elements throughout the specification.

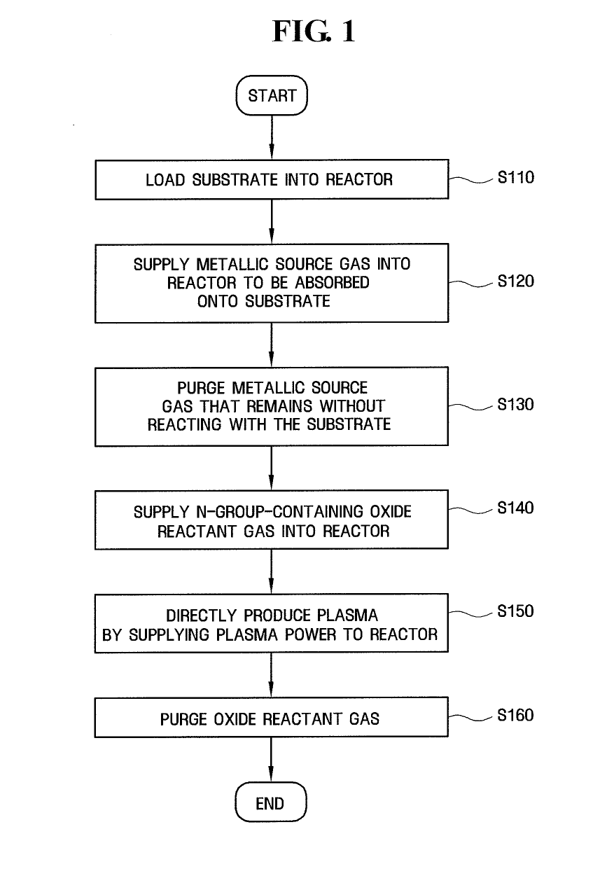

A method of forming a metallic oxide film using ALD according to an embodiment of the invention is described in detail hereafter with reference to FIG. 1. FIG. 1 is a flowchart illustrating a method of forming a metallic oxide film using ALD according to an embodiment of the invention.

Referring to FIG. 1, a substrate is loaded inside a reactor (S110).

The substrate is a three-dimensional structure, and for example, may be a structure having a deep hole, such as a lower electrode of a cylindrical capacitor. The reactor with the substrate loaded may have double chambers, which includes an outer chamber for increasing vacuum in the reactor by blocking outside air and an inner chamber that is provided in the outer chamber and actual reactance occurs therein. Such a reactor improves reactance efficiency due to small reactance space where reactance actually occurs. The volume of reactance space of the inner chamber of the reactor may be, for example, 2000 cc or less, and more preferably 1000 cc or less. In addition, a lateral flow type method may be used to supply a metallic source gas and a metallic reactant gas into the reactor.

Following loading, a metallic source gas is supplied into the reactor and absorbed (S120).

In this process, the provided metallic source gas is varied depending on the type of intended metallic oxide films, but a metallic source gas containing a metal of the intended metallic oxide film may be used. The intended metallic oxide film, for example, may be a hafnium oxide film, zirconium oxide film, aluminum oxide film, titanium oxide film, tantalum oxide film, lanthanum oxide film, praseodymium oxide film, tungsten oxide film, niobium oxide film, molybdenum oxide film, strontium oxide film, barium oxide film, or combinations of the forgoing. Further, it may be a ruthenium oxide film or iridium oxide film, or a combination thereof.

When an aluminum oxide film is formed, a metallic source gas to be supplied, for example, may be TMA (Tri Methyl Aluminum), DMAH (Di Methyl Aluminum Hydride), or DMAH-EPP (DiMethyl Aluminum Hydride Ethyl PiPeridine). When a hafnium oxide film is formed. THMAH (Tetrakis EthylMethylAmino Hafnium), TDEAH (Tetrakis DiethylAmino Hafnium), or TDMAH (Tetrakis DiMethyl Amino Hafnium) may be used. Further, when a zirconium oxide film is formed, TEMAZ (Tetrakis EthylMethylAmino Zirconium), TDEAZ (Tetrakis DiEthylAmino Zirconium), or TDMAZ (Tetrakis DiMethylAmino Zirconium) may be used.

When a metallic source gas is supplied into the reactor for a predetermined time, some of it reacts with the substrate surface or is chemically absorbed onto the surface, and the remainder is physically absorbed onto the reacted or chemically absorbed surface of the metallic source gas or remains inside the reactor.

An inert gas may be supplied together with the metallic source gas. The inert, gas may be, for example, Ar, He, Kr, Xe, or a combination of them.

In the subsequent process, a metallic source gas that remains without reacting with the substrate is purged (S130). The metallic source gas is purged by supplying a purge gas, which may be an inert gas.

In the subsequent process, an N-group-containing oxide reactant gas is supplied into the reactor (S140). The N-group-containing oxide reactant gas may be, for example, N₂O, NO, or NO₂. As for the process, N₂O of 5 to 2000 sccm may be supplied from 50 to 5000° C. and from 100 mTorr to 10 Torr. In particular, N₂O of 10 to 1000 sccm may be supplied from 200 to 400° C. and from 1 to 5 Torr.

In the subsequent process, plasma is formed directly by supplying plasma power to the reactor (S150).

In other words, plasma is directly produced by supplying plasma power into the reactor. The supplied plasma power, for example, is about 50 to 2000 W, or more specifically about 100 to 1000 W. As for ALD using plasma, matching control of plasma is important. The matching values are different or similar depending on the type of metallic oxide films when O₂ plasma and N₂O plasma are formed. Accordingly, as for a complex film containing a variety of substances, an N-group-containing metallic reactant gas or a non-N-group metallic reactant gas is used for each film, but it is required to produce plasma by making matching values different for each case.

The rate of deposition of a metallic oxide film increases when an N-group-containing oxide reactant gas is produced to form a metallic oxide film compared with a non-N-group-oxide reactant gas. For example, the rate of deposition increases about 1.7 times when a metallic oxide film is formed while N₂O plasma is supplied compared with O₂ plasma.

In the subsequent process, an oxide reactant gas is purged (S160). The oxide reactant gas is purged by supplying a purge gas, which may be an inert gas.

According to the method of forming a metallic oxide film using ALD according to an embodiment of the invention, the supplying of a metallic source gas, the purging of the metallic source gas, the direct production of an N-group-containing oxide reactant gas plasma, and the purging of the oxide reactant gas may be repeated.

According to the method of forming a metallic oxide film using ALD according to an embodiment of the invention, a metallic oxide film is formed by producing plasma of an N-group-containing oxide reactant gas. The rate of deposition of the metallic oxide film can increase when plasma of an N-group-containing oxide reactant gas is produced to form the metallic oxide film compared with a non-N-group oxide reactant gas. Accordingly, processes can be performed faster and time can be saved, thus the productivity can be improved.

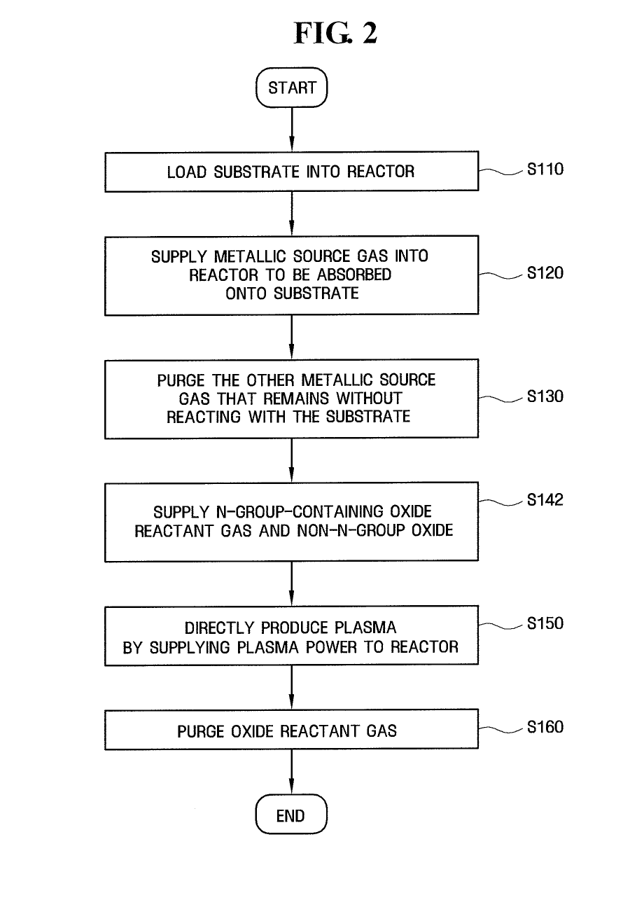

A method of forming a metallic oxide film using ALD according to another embodiment of the invention is described in detail hereafter with reference to FIG. 2. FIG. 2 is a flowchart illustrating a method of forming a metallic oxide film using ALD according to another embodiment of the invention.

Referring to FIG. 2, the loading of a substrate into a reactor, the supplying and absorbing of a metallic source gas onto the substrate, and the purging of a metallic source gas that remains without reacting with the substrate are the same as in the method of forming a metallic oxide film using ALD according to the embodiment of FIG. 1. In other words, the steps before S130 are the same as those in FIG. 1, so that the next steps will be described hereafter.

In the subsequent process, an N-group-containing oxide reactant gas and a non-N-group oxide reactant gas are supplied into the reactor (S142).

The N-group-containing oxide reactant gas may be, for example, N₂O, NO, or NO₂ and the non-N-group oxide reactant gas may be, for example, O₂, O₃, H₂O, or a combination of them. When the N-group-containing oxide reactant gas is supplied together with the non-N-group oxide reactant gas, the rate of deposition of a metallic oxide film increases. In more detail, not only when the N-group-containing oxide reactant gas is the only gas supplied, but also when the N-group-containing oxide reactant gas is supplied together with the non-N-group oxide reactant gas, the rate of deposition increases as far as the N-group-containing oxide reactant gas is supplied above a predetermined ratio. The ratio of the N-group-containing oxide reactant gas and the non-N-group reactant gas may be ⅛ or more.

The subsequent processes of directly producing plasma by supplying plasma power to the reactor and purging of the oxide reactant gas are the same as in the method of forming a metallic oxide film using ALD according to the embodiment of FIG. 1.

According to the method of forming a metallic oxide film using ALD according to this embodiment of the invention, the supplying of a metallic source gas, the purging of the metallic source gas, the direct production of plasma of the N-group-containing oxide reactant gas and the non-N-group oxide reactant gas, and the purging of the oxide reactant gas may also be repeated.

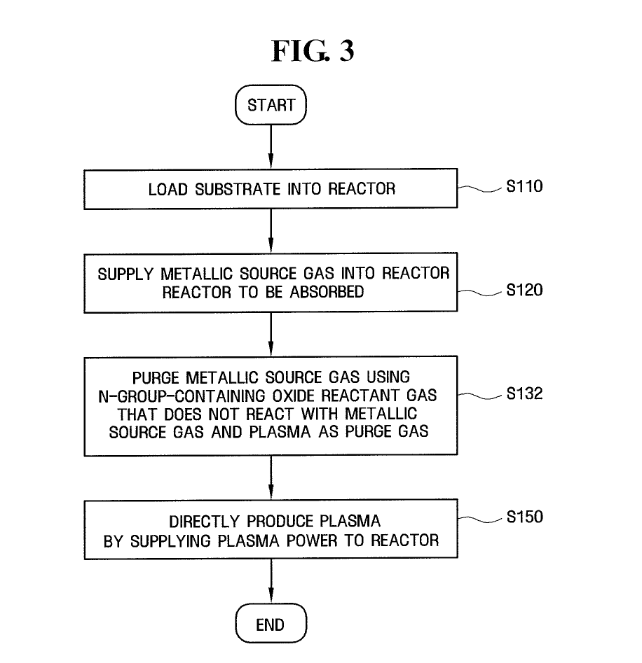

A method of forming a metallic oxide film using ALD according to another embodiment of the invention is described in detail hereafter with reference to FIG. 3. FIG. 3 is a flowchart illustrating a method of forming a metallic oxide film using ALD according to another embodiment of the invention.

Referring to FIG. 3, the loading of a substrate into the reactor, and the supplying and absorbing of the metallic source gas onto the substrate are the same as the method of forming a metallic oxide film using ALD according to the embodiment of FIG. 1. In other words, the steps before S120 are the same as those in FIG. 1, so that the next steps are described hereafter.

In the subsequent process, a metallic source gas is purged using an N-group-containing oxide reactant gas, which does not react with a metallic source gas and plasma, as a purge gas (S132).

Only an N-group-containing oxide reactant gas may be supplied, or it may be supplied together with a non-N-group oxide reactant gas. However, an oxide reactant gas that does not react with a metallic source gas and plasma is used as a purge gas. The N-group-containing oxide reactant gas may be, for example, N₂O, NO, or NO₂ and the non-N-group oxide reactant gas may be, for example, O₂, O₃, H₂O, or combinations of them.

In the subsequent process, plasma power is supplied into the reactor and plasma is directly produced (S150).

According to the method of forming a metallic oxide film using ALD according to this embodiment, the supplying of a metallic source gas, the purging of a metallic source gas using an N-group-containing oxide reactant gas, which does not react with a metallic source gas and plasma, as a purge gas, the direct production of plasma of the oxide reactant gas, and the purging of the oxide reactant gas may also be repeated.

According to the method of forming a metallic oxide film using ALD of the present embodiment of the invention, the rate of deposition can increase when plasma of the N-group-containing oxide reactant gas is produced to form a metallic oxide film compared with plasma of the N-group-non-containing oxide reactant gas. Accordingly, the processes are performed faster and the time is saved, thus the productivity is improved.

Further, the process of repeatedly supplying an oxide reactant gas into the reactor after the purging can be omitted by producing plasma using the oxide reactant gas as a purge gas and supplying plasma power to the purge gas to produce plasma. Accordingly, the time for processing can be reduced and the productivity can be improved. In addition, the cost is saved and the unit cost can be reduced by not separately using a purge gas and an oxide reactant gas.

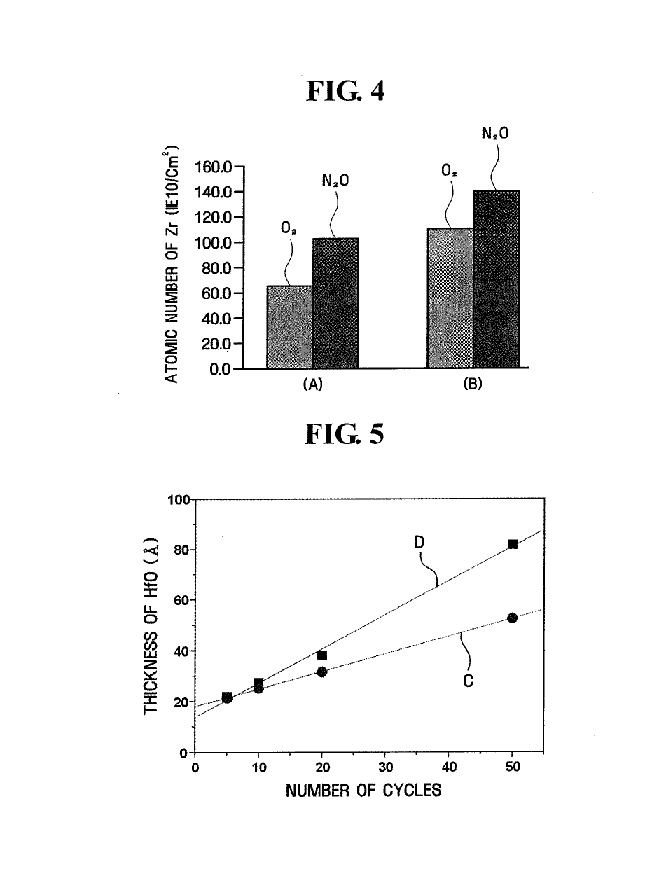

FIG. 4 is a graph showing analysis results of absorption rate and desorption rate of a metallic source gas according to the type of metallic reactant plasma forming gases in the method of forming a metallic oxide film using ALD according to the first embodiment of the invention.

FIG. 4 is a graph showing analysis results of absorption rate and desorption rate of a hafnium when a hafnium oxide film is formed. In ALD of a hafnium oxide film, it is difficult to directly analyze the amount of hafnium to compare the absorbed amounts of hafnium under different conditions, because a large amount of hafnium is absorbed in ALD and the differences in absorbed hafnium under different conditions are small compared with the amount of absorbed hafnium. Accordingly, the amount of absorbed hafnium is estimated by analyzing the small amount of zirconium (Zr) contained in the hafnium. The hafnium and zirconium are extracted from the same mineral, so that a small amount of zirconium is contained in the hafnium. Therefore, the amount of hafnium can be estimated by analyzing the amount of zirconium.

The bar graph of (A) shows the atomic numbers of zirconium per unit area for one cycle when TEMAH that is a metallic source gas for the hafnium is supplied and purged, and then O₂ plasma is supplied, and when TEMAH is supplied and purged, and then N₂O plasma is supplied.

As seen from (A) of FIG. 4, the atomic number of zirconium detected per unit area when N₂O plasma was supplied was 1.53 times more than that of O₂ plasma. Accordingly, it is estimated that the hafnium to be detected when N₂O plasma was supplied is 1.5 times more than that of O₂ plasma. When a metallic source gas is absorbed onto the substrate and plasma of a metallic reactant gas is produced, a part of the absorbed metallic source gas is attached/detached. The attachment/detachment rate when N₂O plasma is supplied is decreased compared with O₂ plasma, so that it is estimated that more hafnium is absorbed.

The bar graph of (B) shows the atomic numbers of zirconium per unit area for one cycle, when O₂ plasma is supplied and purged and then the TEMAH that is a metallic source gas for the hafnium is supplied and when N₂O plasma is supplied and purged, and then TEMAH that is a metallic source gas for the hafnium is supplied.

As seen from (B) of FIG. 4, the atomic number of zirconium detected per unit area when N₂O plasma was supplied is 1.3 times more than that of O₂ plasma. Accordingly, it is estimated that the hafnium to be detected when N₂O plasma was supplied is 1.3 more than that of O₂ plasma. The difference in the absorption rates of the metallic source gas are caused by shadow effects, etc., in ALD. The absorption rate when N₂O plasma is supplied is larger than that when O₂ plasma is supplied and it is estimated that more hafnium is absorbed.

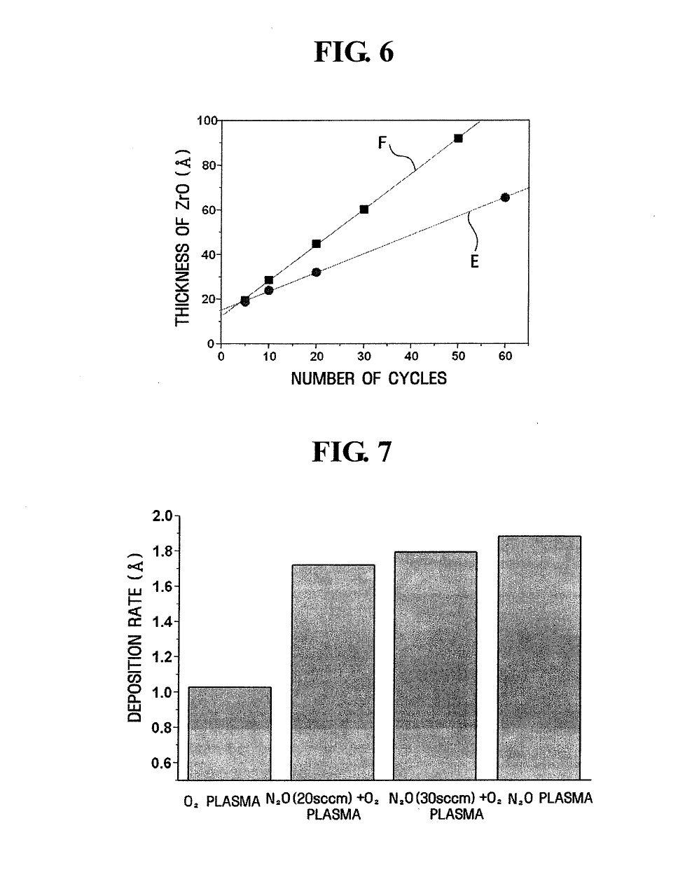

FIGS. 5 and 6 are graphs showing deposition thicknesses of a metallic oxide film according to the type of metallic reactant plasma forming gases in a method of forming a metallic oxide film using ALD according to an embodiment of the invention.

The line C of FIG. 5 is a graph analyzing the thickness of a hafnium oxide film for one cycle of supplying and purging of TEMAH and then producing and purging of O₂ plasma under a processing atmosphere of 300° C. and 3 Torr. The line D is a graph analyzing the thickness of a hafnium oxide film for one cycle of supplying and purging of TEMAH and then producing and purging of N₂O plasma under a processing atmosphere of 300° C. and 3 Torr.

Referring to FIG. 5, the slope of line C is about 0.84 and the slope of the line D is about 1.60. In other words, it can be seen from the figure that the thickness of the hafnium oxide film increases about 1.9 times when N₂O plasma is supplied to form the hafnium oxide film compared with O₂ plasma.

The line E of FIG. 6 is a graph analyzing the thickness of a zirconium oxide film for one cycle of supplying and purging of TEMAZ and then producing and purging of O₂ plasma under a processing atmosphere of 300° C. and 3 Torr. The line F is a graph analyzing the thickness of the zirconium oxide film for one cycle of supplying and purging of TEMAZ and then producing and purging of N₂O plasma under a processing atmosphere of 300° C. and 3 Torr.

Referring to FIG. 6, the slope of line E is about 0.69 and the slope of the line F is about 1.34. In other words, it can be seen from the figure that the thickness of the zirconium oxide film increases about 2.3 times when N₂O plasma is supplied to form the zirconium oxide film compared with O₂ plasma.

FIG. 7 is a graph showing results of analyzing the deposition rate of a metallic oxide film according to the type of metallic reactant plasma forming gases in a method of forming a metallic oxide film using ALD according to an embodiment of the invention.

TEMAH is supplied and purged under a processing atmosphere of 300° C. and 3 Torr, and then different plasma producing metallic reactant gases are supplied. Considering the deposition rate per one cycle when plasma is produced by supplying 150 sccm of O₂ as 1, it can be seen from the figure that the deposition rate increased about 1.72 times when 150 sccm of O₂ and 20 sccm of N₂O were supplied. Further, the deposition rate increased about 1.79 times when 150 sccm of O₂ and 30 sccm of N₂O were supplied. On the other hand, the deposition rate increased about 1.81 times when 150 sccm of N₂O was supplied.

Accordingly, it can be seen that not only when plasma is produced by an N-group-containing oxide reactant gas to form a metallic oxide film, but also when an N-group-containing oxide reactant gas is supplied together with a non-N-group oxide reactant gas to produce plasma, the deposition rate increases compared with when a non-N-group oxide reactant gas is supplied to produce plasma.

Although the present invention has been described in connection with exemplary embodiments, it will be apparent to those skilled in the art that various modifications and changes may be made thereto without departing from the scope and spirit of the invention. Therefore, it should be understood that the above embodiments are not limitative, but illustrative in all aspects.

According to the above methods of forming a metallic oxide film using ALD, at least one effect of the following can be achieved.

First, it is possible to increase the deposition rate of a metallic oxide film by producing plasma using an N-group-containing oxide reactant gas to produce a metallic oxide film.

Second, because the deposition rate of a metallic oxide film increases, the processes are performed faster and the time is saved, thus the productivity can be improved.

Finally, it is possible to reduce processing time and save cost by supplying plasma power to a purge gas to produce plasma.

What is claimed is:

1. A method of forming a metallic oxide film using Atomic Layer Deposition, the method comprising:
loading a substrate into a reactor;
supplying a metallic source gas into the reactor and absorbing at least some of the metallic source gas onto the substrate;
purging the remaining metallic source gas that does not react with the substrate; and
supplying plasma of an N-group containing oxide reactant gas into the reactor.

2. The method of claim 1, wherein supplying plasma of an N-group containing oxide reactant gas into the reactor comprises supplying an N-group containing oxide reactant gas into the reactor and directly producing plasma by supplying plasma power to the reactor.

3. The method of claim 2, wherein the N-group-containing oxide reactant gas is N₂O, NO, or NO₂.

4. The method of claim 2, wherein a non-N-group oxide reactant gas is supplied together with the N-group-containing oxide reactant gas in the producing of plasma.

5. The method of claim 4, wherein the non-N-group oxide reactant gas is O₂, O₃, H₂O, or a mixture thereof.

6. The method of claim 4, wherein the ratio of the N-group-containing oxide reactant gas and the non-N-group oxide reactant gas is about ⅛ or more.

7. The method of claim 1, wherein an inert gas is supplied together with the metallic source gas.

8. The method of claim 7, wherein the inert gas is Ar, He, Kr, Xe, or a mixture thereof.

9. The method of claim 1, further comprising supplying a purge gas wherein the remaining non-reacting metallic source gas is purged.

10. The method of claim 1, further comprising purging the oxide reactant gas after producing the plasma.

11. The method of claim 1, wherein the supplying of a metallic source gas, the purging of the metallic source gas, and the producing of plasma of an oxide reactant gas are repetitively applied.

12. The method of claim 1, wherein the metallic oxide film is a hafnium oxide film, zirconium oxide film, aluminum oxide film, titanium oxide film, tantalum oxide film, lanthanum oxide film, praseodymium oxide film, tungsten oxide film, niobium oxide film, molybdenum oxide film, strontium oxide film, barium oxide film, or a combination of thereof.

13. The method of claim 1, wherein the metallic oxide film is a ruthenium oxide film, a iridium oxide film, or a combination of thereof.

14. The method of claim 1, wherein the reactor comprises an inner chamber and an outer chamber and the substrate is provided in the inner chamber.

15. The method of claim 15, wherein the volume of the inner chamber is about 2000 cc or less.

16. The method of claim 16, wherein the volume of the inner chamber is about 1000 cc or less.

17. The method of claim 1, wherein the reactor is a lateral flow type.

18. A method of forming a metallic oxide film using Atomic Layer Deposition, the method comprising;
loading a substrate into a reactor;
supplying a metallic source gas into the reactor and absorbing at least some of the metallic source gas onto the substrate;
purging the metallic source gas with an N-group-containing oxide reactant gas; and
directly producing plasma of the N-group-containing oxide reactant gas by supplying plasma power to the reactor.

19. The method of claim 18, wherein the oxide reactant gas comprises a non-N-group oxide reactant gas.

20. The method of claim 18, further comprising purging the oxide reactant gas.

21. The method of claim 20, wherein the steps of supplying a metallic source gas, purging the metallic source gas, directly producing plasma, and purging the oxide reactant gas are repetitively applied.
